(19) United States
(12) Patent Application Publication
(10) Pub. No.: US 2024/0071901 A1
(43) Pub. Date: Feb. 29, 2024

(54) CAPACITOR STRUCTURE AND SEMICONDUCTOR STRUCTURE

(71) Applicant: Powerchip Semiconductor Manufacturing Corporation, Hsinchu (TW)

(72) Inventor: Wei-Yu Lin, Hsinchu City (TW)

(73) Assignee: Powerchip Semiconductor Manufacturing Corporation, Hsinchu (TW)

(21) Appl. No.: 17/950,057

(22) Filed: Sep. 21, 2022

(30) Foreign Application Priority Data
Aug. 23, 2022 (TW) 111131726

(51) Int. Cl. H01L 23/522; H01G 4/232; H01L 49/02

(52) U.S. Cl. CPC H01L 23/5223; H01G 4/232; H01L 28/75

(57) ABSTRACT

A capacitor structure including a substrate, an insulating layer, a capacitor, a shielding layer, a first connection terminal, and a second connection terminal is disposed. The insulating layer is disposed on the substrate. The capacitor includes a first electrode layer, a second electrode layer, a dielectric layer. The first electrode layer is disposed on the insulating layer. The second electrode layer is disposed on the first electrode layer. The dielectric layer is disposed between the first electrode layer and the second electrode layer. The shielding layer is disposed in the insulating layer. The shielding layer is located between the first electrode layer and the substrate. The first connection terminal is electrically connected to the first electrode layer. The second connection terminal is electrically connected to the second electrode layer.

### CROSS-REFERENCE TO RELATED APPLICATION

This application claims the priority benefit of Taiwan application serial no. 111131726, filed on Aug. 23, 2022. The entirety of the above-mentioned patent application is hereby incorporated by reference herein and made a part of this specification.

### BACKGROUND

### Technical Field

The disclosure relates to a passive device and a semiconductor structure, and particularly, to a capacitor structure and a semiconductor structure having the same.

### Description of Related Art

Capacitors are passive components widely applied to electronic products. In some capacitor structures, a capacitor is disposed on a substrate, so parasitic capacitance is generated between the electrodes of the capacitor and the substrate. The parasitic capacitance generated between the electrodes of the capacitor and the substrate has a lower quality factor (Q factor), so the quality factor of the capacitor structure is reduced, and this in turn leads to poor performance and efficiency of the capacitor structure and greater energy losses.

### SUMMARY

The disclosure provides a capacitor structure and a semiconductor structure having the same, which can have a higher quality factor.

A capacitor structure including a substrate, an insulating layer, a capacitor, a shielding layer, a first connection terminal, and a second connection terminal is proposed in the disclosure. The insulating layer is disposed on the substrate. The capacitor includes a first electrode layer, a second electrode layer, and a dielectric layer. The first electrode layer is disposed on the insulating layer. The second electrode layer is disposed on the first electrode layer. The dielectric layer is disposed between the first electrode layer and the second electrode layer. The shielding layer is disposed in the insulating layer and located between the first electrode layer and the substrate. The first connection terminal is electrically connected to the first electrode layer. The second connection terminal is electrically connected to the second electrode layer.

According to an embodiment of the disclosure, in the capacitor structure, the shielding layer is further disposed between the second electrode layer and the substrate.

According to an embodiment of the disclosure, in the capacitor structure, the shielding layer includes a metal layer.

According to an embodiment of the disclosure, in the capacitor structure, resistance of the shielding layer is less than resistance of the substrate.

According to an embodiment of the disclosure, in the capacitor structure, a vertical projection of part of the second electrode layer is located on the first electrode layer.

According to an embodiment of the disclosure, in the capacitor structure, a vertical projection of the entire second electrode layer is located on the first electrode layer.

According to an embodiment of the disclosure, in the capacitor structure, a vertical projection of the entire first electrode layer is located on the shielding layer.

According to an embodiment of the disclosure, in the capacitor structure, a vertical projection of the entire second electrode layer is located on the shielding layer.

According to an embodiment of the disclosure, in the capacitor structure, the second electrode layer includes an overlapping portion and a non-overlapping portion. The overlapping portion is overlapped with the first electrode layer. The non-overlapping portion is not overlapped with the first electrode layer.

According to an embodiment of the disclosure, in the capacitor structure, an upper surface of the non-overlapping portion is lower than a top surface of the overlapping portion.

According to an embodiment of the disclosure, in the capacitor structure, a width of the second electrode layer is less than a width of the first electrode layer.

According to an embodiment of the disclosure, in the capacitor structure, the dielectric layer is further disposed between the second electrode layer and the insulating layer.

According to an embodiment of the disclosure, in the capacitor structure, the first connection terminal is an outermost layer of the capacitor structure.

According to an embodiment of the disclosure, in the capacitor structure, a top surface of the first connection terminal is not covered by other components in the capacitor structure.

According to an embodiment of the disclosure, in the capacitor structure, the second connection terminal is an outermost layer of the capacitor structure.

According to an embodiment of the disclosure, in the capacitor structure, a top surface of the second connection terminal is not covered by other components in the capacitor structure.

According to an embodiment of the disclosure, the capacitor structure may further include spacers disposed on sidewalls of the first electrode layer.

According to an embodiment of the disclosure, the capacitor structure may further include a passivation layer. The passivation layer is disposed on the dielectric layer and the second electrode layer. The first connection terminal is electrically connected to the first electrode layer through the passivation layer and the dielectric layer, and the second connection terminal is electrically connected to the second electrode layer through the passivation layer.

According to an embodiment of the disclosure, in the capacitor structure, for example, the first connection terminal and the second connection terminal are under-bump metallization, a bump, or a combination thereof.

The disclosure provides a semiconductor structure, including a circuit board and the capacitor structure. The capacitor structure is bonded to the circuit board.

In summary, in the capacitor structure and the semiconductor structure of the disclosure, since the shielding layer is located between the first electrode layer and the substrate, parasitic capacitance with a lower quality factor can be prevented from being generated between the first electrode layer and the substrate. Accordingly, in the capacitor structure, no parasitic capacitance with a lower quality factor is generated between the first electrode layer and the substrate, so the capacitor structure can have a higher quality factor, thereby improving the performance and the efficiency of the capacitor structure as well as reducing the energy loss.

In order to make the features and advantages of the disclosure comprehensible, embodiments accompanied with drawings are described in detail below.

### BRIEF DESCRIPTION OF THE DRAWING

FIG. 1 is a cross-sectional view of a capacitor structure according to some embodiments of the disclosure.

FIG. 2 is a cross-sectional view of a semiconductor structure according to some embodiments of the disclosure.

FIG. 3 is a cross-sectional view of a capacitor structure according to other embodiments of the disclosure.

FIG. 4 is a cross-sectional view of a semiconductor structure according to other embodiments of the disclosure.

### DESCRIPTION OF THE EMBODIMENTS

Embodiments with reference to the accompanying drawings are illustrated in detail in the specification, but the embodiments are not intended to limit the scope of the disclosure. To facilitate comprehension, same components are illustrated with the same reference numerals in the specification. In addition, for illustrative purposes, specific components in the drawings are not necessarily drawn to scale. In fact, for clarity, a relative size of different features may be reduced or enlarged.

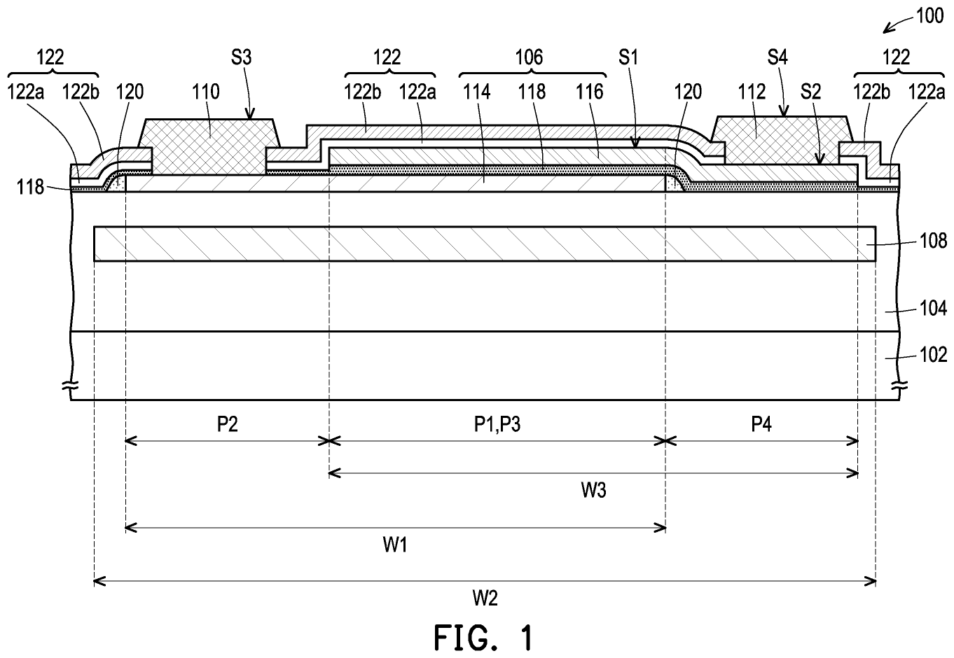

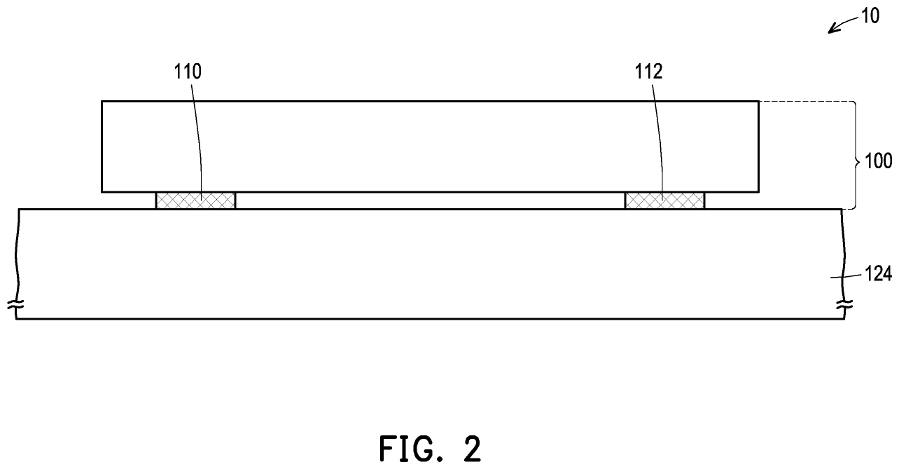

FIG. 1 is a cross-sectional view of a capacitor structure according to some embodiments of the disclosure. FIG. 2 is a cross-sectional view of a semiconductor structure according to some embodiments of the disclosure.

Referring to FIG. 1, a capacitor structure 100 includes a substrate 102, an insulating layer 104, a capacitor 106, a shielding layer 108, a connection terminal 110, and a connection terminal 112. In some embodiments, the substrate 102 may be a semiconductor substrate, such as a silicon substrate. In some embodiments, the capacitor structure 100 may be a silicon capacitor.

The insulating layer 104 is disposed on the substrate 102. In some embodiments, the insulating layer 104 may be a multi-layer structure. In some embodiments, for example, the material of the insulating layer 104 is a dielectric material, such as silicon oxide.

The capacitor 106 includes an electrode layer 114, an electrode layer 116, and a dielectric layer 118. The electrode layer 114 is disposed on the insulating layer 104. In some embodiments, the electrode layer 114 may include an overlapping portion P1 and a non-overlapping portion P2. In some embodiments, the overlapping portion P1 may be overlapped with the electrode layer 116. In some embodiments, the non-overlapping portion P2 is not overlapped with the electrode layer 116. In some embodiments, the electrode layer 114 may be a metal layer. In some embodiments, the material of the electrode layer 114 is aluminum, for example.

The electrode layer 116 is disposed on the electrode layer 114. In the embodiment, the vertical projection of part of the electrode layer 116 may be located on the electrode layer 114. In the embodiment, the electrode layer 116 may include an overlapping portion P3 and a non-overlapping portion P4. In some embodiments, the overlapping portion P3 may be overlapped with the electrode layer 114. In some embodiments, the non-overlapping portion P4 is not overlapped with the electrode layer 114. In some embodiments, an upper surface S2 of the non-overlapping portion P4 may be lower than a top surface S1 of the overlapping portion P3. In some embodiments, the electrode layer 116 may be a metal layer. In some embodiments, the material of the electrode layer 116 is aluminum, for example.

The dielectric layer 118 is disposed between the electrode layer 114 and the electrode layer 116. In some embodiments, the dielectric layer 118 may be further disposed on the electrode layer 114 and the insulating layer 104. In the embodiment, the dielectric layer 118 may be further disposed between the electrode layer 116 and the insulating layer 104. The dielectric layer 118 may be a single-layer structure or a multi-layer structure. In some embodiments, for example, the dielectric layer 118 is a silicon oxide layer, a silicon nitride layer, a composite layer of a silicon oxide layer/silicon nitride layer (ON), a composite layer of a silicon oxide layer/silicon nitride layer/silicon oxide layer (ONO), or a material layer with a high dielectric constant.

The shielding layer 108 is disposed in the insulating layer 104. In addition, the shielding layer 108 is located between the electrode layer 114 and the substrate 102. In some embodiments, the vertical projection of the entire electrode layer 114 may be located on the shielding layer 108. In some embodiments, a width W1 of the electrode layer 114 may be less than a width W2 of the shielding layer 108. The shielding layer 108 is located between the electrode layer 114 and the substrate 102, so the shielding layer 108 can prevent parasitic capacitance with a lower quality factor from being generated between the electrode layer 114 and the substrate 102, thereby allowing the capacitor structure 100 to have a higher quality factor. In some embodiments, the shielding layer 108 may be further located between the electrode layer 116 and the substrate 102. In some embodiments, the vertical projection of the entire electrode layer 116 may be located on the shielding layer 108. In some embodiments, a width W3 of the electrode layer 116 may be less than the width W2 of the shielding layer 108. The shielding layer 108 can be located between the electrode layer 116 and the substrate 102, so the shielding layer 108 can prevent parasitic capacitance with a lower quality factor from being generated between the electrode layer 116 and the substrate 102, thereby allowing the capacitor structure 100 to have a higher quality factor. In some embodiments, the shielding layer 108 may be a metal layer. In some embodiments, the material of the shielding layer 108 is aluminum or copper, for example.

In some embodiments, the resistance of the shielding layer 108 may be less than the resistance of the substrate 102. Since the resistance of the shielding layer 108 may be less than the resistance of the substrate 102 (i.e., the shielding layer 108 may have a lower resistance), the parasitic capacitance generated between the electrode layer 114 and the shielding layer 108 may have a higher quality factor, and the parasitic capacitance generated between the electrode layer 116 and the shielding layer 108 can have a higher quality factor, thereby allowing the capacitor structure 100 to have a higher quality factor.

The connection terminal 110 is electrically connected to the electrode layer 114. In some embodiments, the connection terminal 110 may be connected to the non-overlapping portion P2 of the electrode layer 114, and in some embodiments, the connection terminal 110 may be the outermost layer of the capacitor structure 100. That is, a top surface S3 of the connection terminal 110 is not covered by other components in the capacitor structure 100. In some embodiments, for example, the connection terminal 110 is under-bump metallization (UBM), a bump, or a combination thereof. In some embodiments, for example, the material of the connection terminal 110 is nickel, gold, copper, or a combination thereof.

The connection terminal 112 is electrically connected to the electrode layer 116. In some embodiments, the connection terminal 112 may be the outermost layer of the capacitor structure 100. That is, a top surface S4 of the connection terminal 112 is not covered by other components in the capacitor structure 100. In some embodiments, for example, the connection terminal 112 is under-bump metallization (UBM), a bump, or a combination thereof. In some embodiments, for example, the material of the connection terminal 112 is nickel, gold, copper, or a combination thereof.

In the embodiment, the connection terminal 112 may be connected to the non-overlapping portion P4 of the electrode layer 116, and the upper surface S2 of the non-overlapping portion P4 may be lower than the top surface S1 of the overlapping portion P3. Therefore, the top surface S3 of the connection terminal 110 and the top surface S4 of the connection terminal 112 may have approximately the same height, thereby facilitating the bonding process. In addition, since the connection terminal 112 is connected to the non-overlapping portion P4 of the electrode layer 116, the dielectric layer 118 between the electrode layer 114 and the electrode layer 116 can be prevented from being damaged in the subsequent bonding process. In addition, since the connection terminal 112 is connected to the non-overlapping portion P4 of the electrode layer 116, the overlapping area of the electrode layer 114 and the electrode layer 116 can be adjusted more flexibly, which contributes to the manufacture of the capacitor structure 100 with a smaller capacitance value. In some embodiments, the bonding process can be performed by surface mount technology (SMT) or wire bonding process.

The capacitor structure 100 may further include spacers 120. The spacers 120 are disposed on the sidewalls of the electrode layer 114. In some embodiments, the spacers 120 may be disposed on the insulating layer 104 and located between the dielectric layer 118 and the electrode layer 114. In some embodiments, for example, the material of the spacer 120 is a dielectric material, such as silicon oxide.

The capacitor structure 100 may further include a passivation layer 122. The passivation layer 122 is disposed on the dielectric layer 118 and the electrode layer 116. The connection terminal 110 can be electrically connected to the electrode layer 114 through the passivation layer 122 and the dielectric layer 118. The connection terminal 112 can be electrically connected to the electrode layer 116 through the passivation layer 122. The passivation layer 122 may have a single-layer structure or a multi-layer structure. In the embodiment, the passivation layer 122 is illustrated with a multi-layer structure. For example, the passivation layer 122 may include a passivation layer 122a and a passivation layer 122b, and the passivation layer 122a is disposed on the dielectric layer 118 and the electrode layer 116. In some embodiments, for example, the material of the passivation layer 122a is a dielectric material, such as silicon oxide. The passivation layer 122b is disposed on the passivation layer 122a. In some embodiments, for example, the material of the passivation layer 122b is a dielectric material, such as silicon nitride.

Referring to FIG. 2, a semiconductor structure 10 includes a circuit board 124 and the capacitor structure 100. In some embodiments, the circuit board 124 may be a printed circuit board. The capacitor structure 100 is bonded to the circuit board 124. In the embodiment, the capacitor structure 100 can be bonded to the circuit board 124 by the surface mount technology, but the disclosure is not limited thereto. For example, the capacitor structure 100 may be bonded to the circuit board 124 by solder paste (not shown). In other embodiments, the capacitor structure 100 may be bonded to the circuit board 124 by the wire bonding process. In addition, in FIG. 2, only some components of the capacitor structure 100 are illustrated, and for the detailed content of the capacitor structure 100, refer to the illustration of FIG. 1, which is omitted herein.

According to the foregoing embodiments, in the capacitor structure 100 and the semiconductor structure 10, since the shielding layer 108 is located between the electrode layer 114 and the substrate 102, the parasitic capacitance with a lower quality factor can be prevented from being generated between the electrode layer 114 and the substrate 102. Accordingly, in the capacitor structure 100, no parasitic capacitance with a lower quality factor is generated between the electrode layer 114 and the substrate 102, so the capacitor structure 100 can have a higher quality factor, thereby improving the performance and the efficiency of the capacitor structure 100 as well as reducing the energy loss.

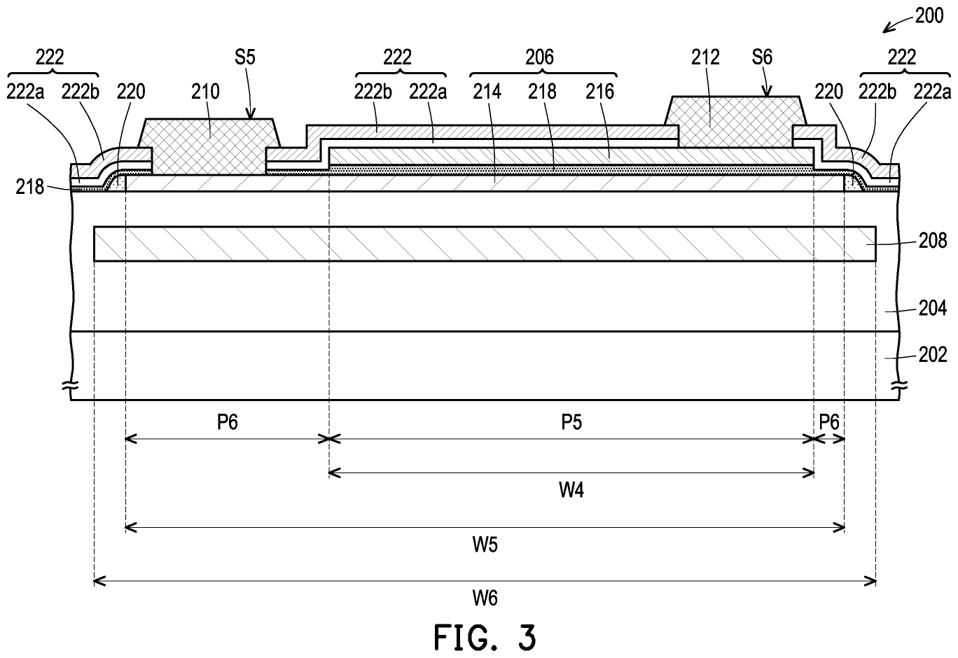

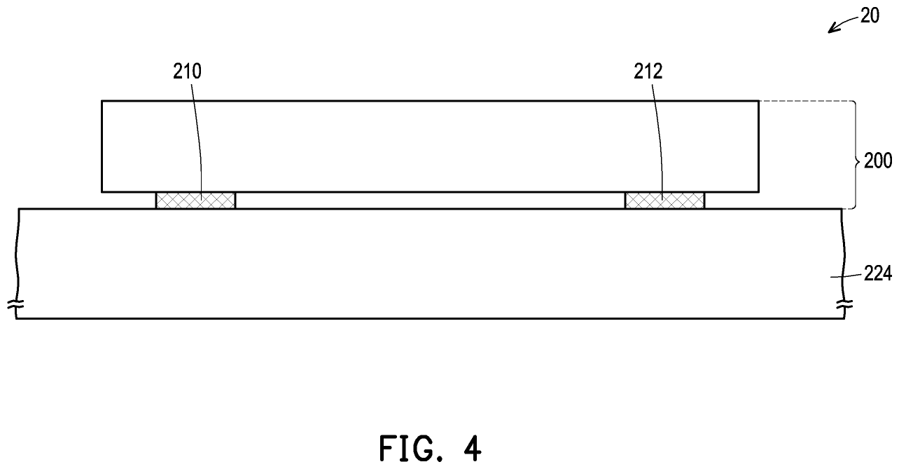

FIG. 3 is a cross-sectional view of a capacitor structure according to other embodiments of the disclosure. FIG. 4 is a cross-sectional view of a semiconductor structure according to other embodiments of the disclosure.

Referring to FIG. 3, a capacitor structure 200 includes a substrate 202, an insulating layer 204, a capacitor 206, a shielding layer 208, a connection terminal 210, and a connection terminal 212. In some embodiments, the substrate 202 may be a semiconductor substrate, such as a silicon substrate. In some embodiments, the capacitor structure 200 may be a silicon capacitor.

The insulating layer 204 is disposed on the substrate 202. In some embodiments, the insulating layer 204 may be a multi-layer structure. In some embodiments, for example, the material of the insulating layer 204 is a dielectric material, such as silicon oxide.

The capacitor 206 includes an electrode layer 214, an electrode layer 216, and a dielectric layer 218. The electrode layer 214 is disposed on the insulating layer 204. In some embodiments, the electrode layer 214 may include an overlapping portion P5 and a non-overlapping portion P6. In some embodiments, the overlapping portion P5 may be overlapped with the electrode layer 216. In some embodiments, the non-overlapping portion P6 is not overlapped with the electrode layer 216. In some embodiments, the electrode layer 214 may be a metal layer. In some embodiments, the material of the electrode layer 214 is aluminum, for example.

The electrode layer 216 is disposed on the electrode layer 214. In the embodiment, the vertical projection of the entire electrode layer 216 may be located on the electrode layer 214. In some embodiments, a width W4 of the electrode layer 216 may be less than a width W5 of the electrode layer 214. In some embodiments, the electrode layer 216 may be a metal layer. In some embodiments, the material of the electrode layer 216 is aluminum, for example.

The dielectric layer 218 is disposed between electrode layer 214 and electrode layer 216. In some embodiments, the dielectric layer 218 may be further disposed on the electrode layer 214 and the insulating layer 204. The dielectric layer 218 may be a single-layer structure or a multi-layer structure. In some embodiments, for example, the dielectric layer 218 is a silicon oxide layer, a silicon nitride layer, a composite layer of a silicon oxide layer/silicon nitride layer (ON), a composite layer of a silicon oxide layer/silicon nitride layer/silicon oxide layer (ONO), or a material layer with a high dielectric constant.

The shielding layer 208 is disposed in the insulating layer 204 between the electrode layer 214 and the substrate 202. In some embodiments, the vertical projection of the entire electrode layer 214 may be located on the shielding layer 208. In some embodiments, the width W5 of the electrode layer 214 may be less than a width W6 of the shielding layer 208. Since the shielding layer 208 is located between the electrode layer 214 and the substrate 202, the shielding layer 208 can prevent parasitic capacitance with a lower quality factor from being generated between the electrode layer 214 and the substrate 202, thereby allowing the capacitor structure 200 to have a higher quality factor. In some embodiments, the shielding layer 208 may be further disposed between the electrode layer 216 and the substrate 202. In some embodiments, the vertical projection of the entire electrode layer 216 may be located on the shielding layer 208. In some embodiments, the width W4 of the electrode layer 216 may be less than the width W6 of the shielding layer 208. In some embodiments, the shielding layer 208 may be a metal layer. In some embodiments, the material of the shielding layer 208 is aluminum or copper, for example.

In some embodiments, the resistance of the shielding layer 208 may be less than the resistance of the substrate 202. Since the resistance of the shielding layer 208 may be less than the resistance of the substrate 202 (i.e., the shielding layer 208 may have a smaller resistance), the parasitic capacitance generated between the electrode layer 214 and the shielding layer 208 may has a higher quality factor, thereby allowing the capacitor structure 200 to have a higher quality factor.

The connection terminal 210 is electrically connected to the electrode layer 214. In some embodiments, the connection terminal 210 may be connected to the non-overlapping portion P6 of the electrode layer 214, and in some embodiments, the connection terminal 210 may be the outermost layer of the capacitor structure 200. That is, the top surface S5 of the connection terminal 210 is not covered by other components in the capacitor structure 200. In some embodiments, for example, the connection terminal 210 is under-bump metallization (UBM), a bump, or a combination thereof. In some embodiments, for example, the material of the connection terminal 210 is nickel, gold, copper, or a combination thereof.

The connection terminal 212 is electrically connected to the electrode layer 216. In some embodiments, the connection terminal 212 may be the outermost layer of the capacitor structure 200. That is, the top surface S6 of the connection terminal 212 is not covered by other components in the capacitor structure 200. In some embodiments, for example, the connection terminals 212 is under-bump metallization (UBM), a bump, or a combination thereof. In some embodiments, for example, the material of the connection terminal 212 is nickel, gold, copper, or a combination thereof.

The capacitor structure 200 may further include spacers 220. The spacers 220 are disposed on sidewalls of the electrode layer 214. In some embodiments, the spacers 220 may be disposed on the insulating layer 204 and located between the dielectric layer 218 and the electrode layer 214. In some embodiments, for example, the material of the spacer 220 is a dielectric material, such as silicon oxide.

The capacitor structure 200 may further include a passivation layer 222. The passivation layer 222 is disposed on the dielectric layer 218 and the electrode layer 216. The connection terminal 210 can be electrically connected to the electrode layer 214 through the passivation layer 222 and the dielectric layer 218. The connection terminal 212 can be electrically connected to the electrode layer 216 through the passivation layer 222. The passivation layer 222 may have a single-layer structure or a multi-layer structure. In the embodiment, the passivation layer 222 is illustrated with a multi-layer structure. For example, the passivation layer 222 may include a passivation layer 222a and a passivation layer 222b, and the passivation layer 222a is disposed on the dielectric layer 218 and the electrode layer 216. In some embodiments, for example, the material of the passivation layer 222a is a dielectric material, such as silicon oxide. The passivation layer 222b is disposed on the passivation layer 222a. In some embodiments, for example, the material of the passivation layer 222b is a dielectric material, such as silicon nitride.

Referring to FIG. 4, a semiconductor structure 20 includes a circuit board 224 and the capacitor structure 200. In some embodiments, the circuit board 224 may be a printed circuit board. The capacitor structure 200 is bonded to the circuit board 224. In the embodiment, the capacitor structure 200 can be bonded to the circuit board 224 by the surface mount technology, but the disclosure is not limited thereto. For example, the capacitor structure 200 may be bonded to the circuit board 224 by solder paste (not shown). In other embodiments, the capacitor structure 200 may be bonded to the circuit board 224 by the wire bonding process. In addition, in FIG. 4, only some components of the capacitor structure 200 are illustrated, and for the detailed content of the capacitor structure 200, refer to the illustration of FIG. 3, which is omitted herein.

According to the foregoing embodiments, in the capacitor structure 200 and the semiconductor structure 20, since the shielding layer 208 is located between the electrode layer 214 and the substrate 202, the parasitic capacitance with a lower quality factor can be prevented from being generated between the electrode layer 214 and the substrate 202. Accordingly, in the capacitor structure 200, no parasitic capacitance with a lower quality factor is generated between the electrode layer 214 and the substrate 202, so the capacitor structure 200 can have a higher quality factor, thereby improving the performance and the efficiency of the capacitor structure 200 as well as reducing the energy loss.

In summary, in the capacitor structure and the semiconductor structure of the embodiments, since the shielding layer is located between the electrode layer and the substrate, parasitic capacitance with a lower quality factor can be prevented from being generated between the electrode layer and the substrate. Accordingly, in the capacitor structure, no parasitic capacitance with a lower quality factor is generated between the electrode layer and the substrate, so the capacitor structure can have a higher quality factor, thereby improving the performance and the efficiency of the capacitor structure as well as reducing the energy loss.

Although the disclosure has been described with reference to the above embodiments, they are not intended to limit the disclosure. It will be apparent to one of ordinary skill in the art that modifications and changes to the described embodiments may be made without departing from the spirit and the scope of the disclosure. Accordingly, the scope of the disclosure will be defined by the attached claims and their equivalents and not by the above detailed descriptions.

What is claimed is:

1. A capacitor structure comprising:
a substrate;
an insulating layer disposed on the substrate;
a capacitor comprising:
a first electrode layer disposed on the insulating layer;
a second electrode layer disposed on the first electrode layer; and
a dielectric layer disposed between the first electrode layer and the second electrode layer;
a shielding layer disposed in the insulating layer and located between the first electrode layer and the substrate;
a first connection terminal electrically connected to the first electrode layer; and
a second connection terminal electrically connected to the second electrode layer.

2. The capacitor structure of claim 1, wherein the shielding layer is further disposed between the second electrode layer and the substrate.

3. The capacitor structure of claim 1, wherein the shielding layer comprises a metal layer.

4. The capacitor structure of claim 1, wherein resistance of the shielding layer is less than resistance of the substrate.

5. The capacitor structure of claim 1, wherein a vertical projection of part of the second electrode layer is located on the first electrode layer.

6. The capacitor structure of claim 1, wherein a vertical projection of the entire second electrode layer is located on the first electrode layer.

7. The capacitor structure of claim 1, wherein a vertical projection of the entire first electrode layer is located on the shielding layer.

8. The capacitor structure of claim 1, wherein a vertical projection of the entire second electrode layer is located on the shielding layer.

9. The capacitor structure of claim 1, wherein the second electrode layer comprises:
an overlapping portion overlapped with the first electrode layer; and
a non-overlapping portion not overlapped with the first electrode layer.

10. The capacitor structure of claim 9, wherein an upper surface of the non-overlapping portion is lower than a top surface of the overlapping portion.

11. The capacitor structure of claim 1, wherein a width of the second electrode layer is less than a width of the first electrode layer.

12. The capacitor structure of claim 1, wherein the dielectric layer is further disposed between the second electrode layer and the insulating layer.

13. The capacitor structure of claim 1, wherein the first connection terminal is an outermost layer of the capacitor structure.

14. The capacitor structure of claim 1, wherein a top surface of the first connection terminal is not covered by other components in the capacitor structure.

15. The capacitor structure of claim 1, wherein the second connection terminal is an outermost layer of the capacitor structure.

16. The capacitor structure of claim 1, wherein a top surface of the second connection terminal is not covered by other components in the capacitor structure.

17. The capacitor structure of claim 1, further comprising:
spacers disposed on sidewalls of the first electrode layer.

18. The capacitor structure of claim 1, further comprising:
a passivation layer disposed on the dielectric layer and the second electrode layer, wherein the first connection terminal is electrically connected to the first electrode layer through the passivation layer and the dielectric layer, and the second connection terminal is electrically connected to the second electrode layer through the passivation layer.

19. The capacitor structure of claim 1, wherein the first connection terminal and the second connection terminal comprise under-bump metallization, a bump, or a combination thereof.

20. A semiconductor structure comprising:
a circuit board; and
the capacitor structure of claim 1, which is bonded to the circuit board.
